(19) United States
(12) Patent Application Publication
(10) Pub. No.: US 2015/0294739 A1
(43) Pub. Date: Oct. 15, 2015

(54) ONLINE HISTOGRAM AND SOFT INFORMATION LEARNING

(71) Applicant: LSI Corporation, San Jose, CA (US)

(72) Inventors: Yu Cai, San Jose, CA (US); Zhengang Chen, San Jose, CA (US); Yunxiang Wu, Cupertino, CA (US); Erich F. Haratsch, Bethlehem, PA (US)

(73) Assignee: LSI Corporation, San Jose, CA (US)

(21) Appl. No.: 14/249,714

(22) Filed: Apr. 10, 2014

(51) Int. Cl. G11C 29/50; G06F 11/10; G06F 11/07; G11C 29/44

(52) U.S. Cl. CPC G11C 29/50004; G11C 29/44; G06F 11/1072; G06F 11/076; G11C 2029/5004

(57) ABSTRACT

A system includes a processor configured to read information from a plurality of memory cells. The processor initiates a first read of raw data from a group of memory cells using a first reference voltage. The processor also initiates a second read of raw data from the group of memory cells using a second reference voltage different from the first reference voltage. The processor further compares the first read to the second read to identify memory cells read with a bit value that changes between the first and second reads. The processor also assigns the memory cells read with a bit value that changes between the first and second reads to a region associated with the second reference voltage. The processor further counts the number of cells read with a bit value that changes to generate a histogram corresponding to soft information for the group of memory cells.

### FIELD OF THE INVENTION

The present disclosure is related to systems and techniques for implementing histogram and soft information learning for electronic computer storage.

### BACKGROUND

Soft-decoded error-correcting code (ECC), such as low-density parity-check (LDPC) code, estimates soft information for each bit read from a memory. For example, with flash memory, a histogram is learned or estimated for flash memory cells. Based on the histogram, soft information can be learned or estimated for the flash memory.

### SUMMARY

A system includes a processor configured to read information from a plurality of memory cells. The processor initiates a first read of raw data from a group of memory cells using a first reference voltage. The processor also initiates a second read of raw data from the group of memory cells using a second reference voltage different from the first reference voltage. The processor further compares the first read to the second read to identify memory cells read with a bit value that changes between the first and second reads. The processor also assigns the memory cells read with a bit value that changes between the first and second reads to a region associated with the second reference voltage. The processor further counts the number of cells read with a bit value that changes to generate a histogram corresponding to soft information for the group of memory cells.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DRAWINGS

The Detailed Description is described with reference to the accompanying figures. The use of the same reference numbers in different instances in the description and the figures may indicate similar or identical items.

FIG. 1 is a diagrammatic illustration of a system including memory and a controller, where the controller is configured to assign memory cells of the memory to regions associated with soft information obtained using multiple reads in accordance with example embodiments of the present disclosure.

FIG. 2 is a diagrammatic illustration of histogram learning based upon disparity with multiple reads for an upper page of memory, such as the memory shown in FIG. 1, where two reference voltages are changed simultaneously to generate soft information.

FIG. 3 is a diagrammatic illustration of histogram learning based upon disparity with multiple reads for a lower page of memory, such as the memory shown in FIG. 1, where memory cells read with a bit value that changes between data reads are assigned to a region associated with soft information in accordance with example embodiments of the present disclosure.

FIG. 4 is a diagrammatic illustration of histogram learning based upon disparity with multiple reads for the lower page of memory shown in FIG. 3, where memory cells read with a bit value that changes between data reads are assigned to a region associated with soft information in accordance with example embodiments of the present disclosure.

FIG. 5 is a diagrammatic illustration of histogram learning based upon disparity with multiple reads for an upper page of memory, such as the memory shown in FIG. 1, where memory cells read with a bit value that changes between data reads are assigned to a region associated with soft information in accordance with example embodiments of the present disclosure.

FIG. 6 is a diagrammatic illustration of histogram learning based upon disparity with multiple reads for the upper page of memory shown in FIG. 5, where memory cells read with a bit value that changes between data reads are assigned to a region associated with soft information in accordance with example embodiments of the present disclosure.

FIG. 7 is a diagrammatic illustration of histogram learning based upon disparity with multiple reads for the upper page of memory shown in FIG. 5, where memory cells read with a bit value that changes between data reads are assigned to a region associated with soft information in accordance with example embodiments of the present disclosure.

FIG. 8 is a diagrammatic illustration of histogram learning based upon disparity with multiple reads for the upper page of memory shown in FIG. 5, where memory cells read with a bit value that changes between data reads are assigned to a region associated with soft information in accordance with example embodiments of the present disclosure.

FIG. 9 is a diagrammatic illustration of a buffer for a controller, such as the controller shown in FIG. 1, where the buffer is configured to store data from memory reads and assign memory cells to regions associated with soft information obtained using multiple reads in accordance with example embodiments of the present disclosure.

FIG. 10 is a diagrammatic illustration of a buffer for a controller, such as the controller shown in FIG. 1, where the buffer is configured to store data from memory reads and assign memory cells to regions associated with soft information obtained using multiple reads in accordance with example embodiments of the present disclosure.

FIG. 11 is a block diagram illustrating a method for assigning memory cells to regions associated with soft information obtained using multiple reads and generating a histogram corresponding to soft information for the memory cells.

### WRITTEN DESCRIPTION

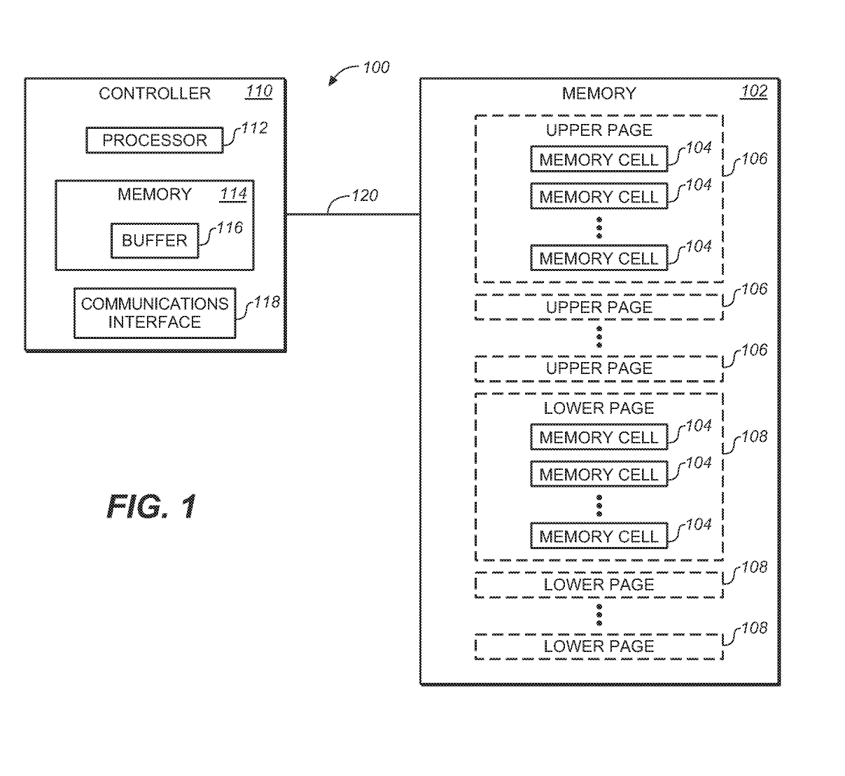

Referring now to FIG. 1, a system 100 is described. The system 100 includes memory 102 for storing information. For example, the memory 102 is implemented as electronic non-volatile computer storage that can be electrically erased and reprogrammed (e.g., flash memory). The memory 102 includes multiple memory cells 104 for storing information (e.g., programs of instructions, data, and so forth). In some embodiments, a memory cell 104 stores one symbol (e.g., a binary digit (bit) representing a value of ‘0’ or ‘1’). In other embodiments, a memory cell 104 stores multiple bits (e.g., a multiple level cell (MLC) such as a two-bit (2-bit) MLC flash memory cell). The memory cells 104 are logically organized into groups (e.g., blocks or pages) for writing and reading the information stored in the memory 102. For example, the memory cells 104 are organized into pages, and information is read from the memory 102 one page at a time. When information is read from the memory 102, soft information can be obtained using, for example, multiple read operations. Such soft information includes, but is not necessarily limited to, a probability corresponding to a confidence in whether a bit value read from the memory 102 is correct. The soft information is then used to correct erroneous bits read from the memory 102. For instance, histogram learning is used to track disparity changes while changing one or more read reference voltages.

In embodiments of the disclosure, the memory 102 includes upper pages 106 and lower pages 108. When information stored in an upper page 106 is read, two different reference voltages are used, and the memory cells 104 in the upper page 106 are logically sorted into regions or bins associated with soft information obtained using multiple reads. For example, an upper page 106 includes a Va region and a Vc region, and reference voltages Va and Vc are used to generate soft information for the regions. Memory cells 104 in the Va region and the Vc region are logically sorted into regions associated with the soft information. For instance, memory cells 104 in the Va region are associated with regions R1, R2, R3, R4, R5, and R6, and memory cells 104 in the Vc region are associated with regions R1′, R2′, R3′, R4′, R5′, and R6′. Each one of the regions R1, R2, R3, R4, R5, R6, R1′, R2′, R3′, R4′, R5′, and R6′ is mapped into a probability corresponding to a confidence in whether a bit value read from a memory cell 104 in that region is correct.

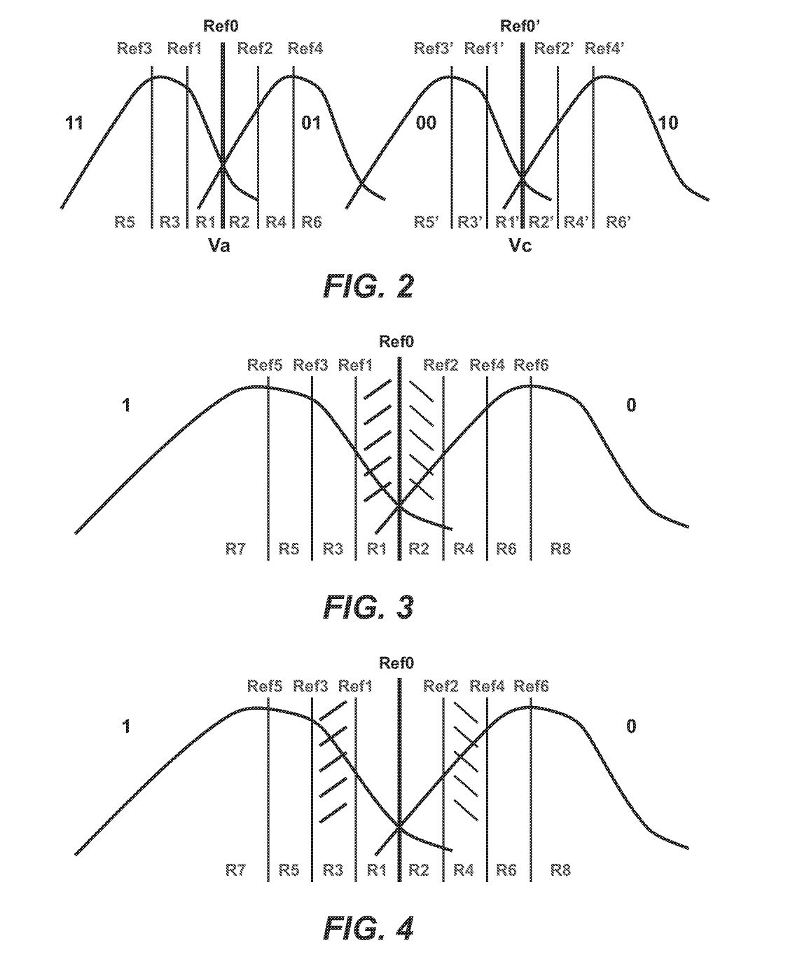

In some cases, a histogram for an upper page 106 of the memory 102 can be learned based upon disparity, using a technique where Va and Vc are changed separately. However, this technique can decrease read-retry performance (e.g., with respect to techniques that change Va and Vc simultaneously). When Va and Vc are changed simultaneously during read-retry of the upper page 106, it can be difficult to determine whether a memory cell 104 is programmed in the Va region or the Vc region of the upper page 106 based upon disparity. For instance, with reference to FIG. 2, histogram learning based upon disparity with multiple reads is described for an upper page 106 of memory 102, where Va and Vc are changed simultaneously. In this example, when Va is changed from Ref0 to Ref1 and Vc is changed from Ref0′ to Ref1′, a decreasing number of memory cells 104 in the R1 region return a read value of ‘1’, and an increasing number of memory cells 104 in the R1′ region return a read value of ‘1’. In this example, the decreasing number of memory cells 104 in the R1 region and the increasing number of memory cells 104 in the R1′ region counteract one another.

With continuing reference to FIG. 2, in another example where Va and Vc are changed simultaneously, when Va is changed from Ref0 to Ref1 and Vc is changed from Ref0′ to Ref2′, a decreasing number of memory cells 104 in the R1 region return a read value of ‘1’, and a decreasing number of memory cells 104 in the R2′ region also return a read value of ‘1’. In this example, the disparity technique determines the total number of cells in regions R1 and R2′ together, but not whether a particular memory cell 104 is in the R1 region or the R2′ region, and not the number of memory cells 104 in regions R1 or R2′ separately.

Referring again to FIG. 1, in embodiments of the disclosure the memory 102 is coupled with a controller 110. The controller 110 is operatively coupled with the memory 102 and receives data read from the memory 104 during multiple reads. The controller 110 is also configured to assign the memory cells 104 of the memory 102 to regions or bins associated with soft information obtained from the multiple reads. For example, the controller 110 includes a processor 112 configured to read data stored in the memory 102, a memory 114 configured to store data received from the memory 102 (e.g., in a buffer 116), a communications interface 118 configured to communicate with the memory 102 (e.g., via a bus 120, such as an eight-bit (8-bit) bit wide bus or a sixteen-bit (16-bit) bit wide bus), and so forth.

Referring now to FIG. 3, histogram learning based upon disparity with multiple reads for a lower page 108 of the memory 102 is described in accordance with example embodiments of the present disclosure. The lower page 108 of the memory 102 is read with reference voltage Ref0, and memory cells 104 with a threshold voltage less than Ref0 are read as ‘1’, while memory cells 104 with a threshold voltage greater than Ref0 are read as ‘0’. The number of memory cells 104 read as ‘1’ is counted as N₁^{step0}, and the number of memory cells 104 read as ‘0’ is counted as N₀^{step0}. Next, the lower page 108 of the memory 102 is read with reference voltage Ref1, and memory cells 104 with a threshold voltage less than Ref1 are read as ‘1’, while memory cells 104 with a threshold voltage greater than Ref1 are read as ‘0’. Compared to the raw page data read with Ref0, memory cells 104 read with a bit value that changes from ‘1’ to ‘0’ are associated with region R1. The number of memory cells 104 read with a bit value that changes from ‘1’ to ‘0’ is counted as N_{1->0}^{step1} and is equal to the number of memory cells 104 in region R1 (denoted N^{R1}).

Then, the lower page 108 of the memory 102 is read with reference voltage Ref2, and memory cells 104 with a threshold voltage less than Ref2 are read as ‘1’, while memory cells 104 with a threshold voltage greater than Ref2 are read as ‘0’. Compared to the data read with Ref1, memory cells 104 read with a bit value that changes from ‘0’ to ‘1’ are associated with regions R1 and R2. The number of memory cells 104 read with a bit value that changes from ‘0’ to ‘1’ is counted as N_{0->1}^{step2} and is equal to the total number of memory cells 104 in regions R1 and R2. Subtracting the number of memory cells 104 in region R1, the number of memory cells 104 with a threshold voltage in region R2 is obtained (denoted N^{R2}=N_{0->1}^{step2}−N^{R1}).

Next, with reference to FIG. 4, the lower page 108 of the memory 102 is read with reference voltage Ref3, and memory cells 104 with a threshold voltage less than Ref3 are read as ‘1’, while memory cells 104 with a threshold voltage greater than Ref3 are read as ‘0’. Compared to the data read with Ref2, memory cells 104 read with a bit value that changes from ‘1’ to ‘0’ are associated with regions R1, R2, and R3. The number of memory cells 104 read with a bit value that changes from ‘1’ to ‘0’ is counted as N_{1->0}^{step3} and is equal to the total number of memory cells 104 in regions R1, R2, and R3. Subtracting the number of memory cells 104 in regions R1 and R2, the number of memory cells 104 with a threshold voltage in region R3 is obtained (denoted N^{R3}=N_{1>0}^{step3}−N^{R1}−N^{R2}).

Then, the lower page 108 of the memory 102 is read with reference voltage Ref4, and memory cells 104 with a threshold voltage less than Ref4 are read as ‘1’, while memory cells 104 with a threshold voltage greater than Ref4 are read as ‘0’. Compared to the data read with Ref3, memory cells 104 read with a bit value that changes from ‘0’ to ‘1’ are associated with regions R1, R2, R3, and R4. The number of memory cells 104 read with a bit value that changes from ‘0’ to ‘1’ is counted as N_{0->1}^{step4} and is equal to the total number of memory cells 104 in regions R1, R2, R3, and R4. Subtracting the number of memory cells 104 in regions R1, R2, and R3, the number of memory cells 104 with a threshold voltage in region R4 is obtained (denoted N^{R4}=N_{0->1}^{step4}−N^{R1}−N^{R2}−N^{R3}). Using this methodology, the numbers of memory cells 104 with threshold voltages programmed in regions R5, R6, R7, R8, and so on are obtained.

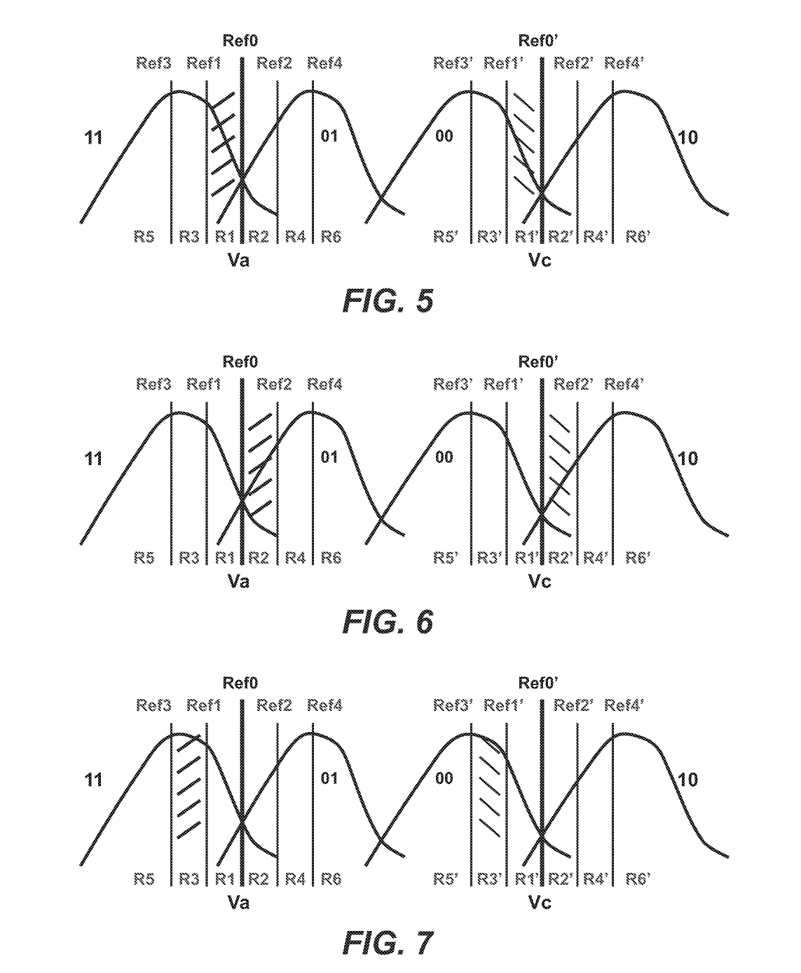

Referring now to FIG. 5, histogram learning based upon disparity with multiple reads for an upper page 106 of the memory 102 is described in accordance with example embodiments of the present disclosure. The upper page 106 of the memory 102 is read with reference voltages Ref0 and Ref0′, and memory cells 104 with a threshold voltage within region [Ref0, Ref0′] are read as ‘0’, while memory cells 104 with a threshold voltage beyond region [Ref0, Ref0′] are read as ‘1’. It should be noted that in embodiments of the disclosure, least significant bit (LSB) assisted reading is not necessarily used to read from the memory 102. The number of memory cells 104 read as ‘1’ is counted as N₁^{step0}, and the number of memory cells 104 read as ‘0’ is counted as N₀^{step0}. Next, the upper page 106 of the memory 102 is read with reference voltages Ref1 and Ref1′, and memory cells 104 with a threshold voltage within region [Ref1, Ref1′] are read as ‘0’, while memory cells 104 with a threshold voltage beyond region [Ref1, Ref1′] are read as ‘1’. Compared to the raw page data read with Ref0 and Ref0′, memory cells 104 read with a bit value that changes from ‘1’ to ‘0’ are associated with region R1. The number of memory cells 104 read with a bit value that changes from ‘1’ to ‘0’ is counted as N_{1->0}^{step1} and is equal to the number of memory cells 104 in region R1 (denoted N^{R1}). Compared to the raw page data read with Ref0 and Ref0′, memory cells 104 read with a bit value that changes from ‘0’ to ‘1’ are associated with region R1′. The number of memory cells 104 read with a bit value that changes from ‘0’ to ‘1’ is counted as N_{0->1}^{step1} and is equal to the number of memory cells 104 in region R1′ (denoted N^{R1′}).

Then, with reference to FIG. 6, the upper page 106 of the memory 102 is read with reference voltages Ref2 and Ref2′, and memory cells 104 with a threshold voltage within region [Ref2, Ref2′] are read as ‘0’, while memory cells 104 with a threshold voltage beyond region [Ref2, Ref2′] are read as ‘1’. Compared to the raw page data read with Ref1 and Ref1′, the number of memory cells 104 read with a bit value that changes from ‘0’ to ‘1’ is counted as N_{0->1}^{step2} and is equal to the total number of memory cells 104 in regions R1 and R2. Subtracting the number of memory cells 104 in region R1, the number of memory cells 104 with a threshold voltage in region R2 is obtained (denoted N^{R2}=N_{0->1}^{step2}−N^{R1}). Compared to the raw page data read with Ref1 and Ref1′, the number of memory cells 104 read with a bit value that changes from ‘1’ to ‘0’ is counted as N_{1->0}^{step2} and is equal to the total number of memory cells 104 in regions R1′ and R2′. Subtracting the number of memory cells 104 in region R1′, the number of memory cells 104 with a threshold voltage in region R2′ is obtained (denoted N^{R2′}=N_{1->0}^{step2}−N^{R1′}).

Next, with reference to FIG. 7, the upper page 106 of the memory 102 is read with reference voltages Ref3 and Ref3′, and memory cells 104 with a threshold voltage within region [Ref3, Ref3′] are read as ‘0’, while memory cells 104 with a threshold voltage beyond region [Ref3, Ref3′] are read as ‘1’. Compared to the raw page data read with Ref2 and Ref2′, the number of memory cells 104 read with a bit value that changes from ‘1’ to ‘0’ is counted as N_{1->0}^{step3} and is equal to the total number of memory cells 104 in regions R1, R2, and R3. Subtracting the number of memory cells 104 in regions R1 and R2, the number of memory cells 104 with a threshold voltage in region R3 is obtained (denoted N^{R3}=N_{0->1}^{step3}−N^{R1}−N^{R2}). Compared to the raw page data read with Ref2 and Ref2′, the number of memory cells 104 read with a bit value that changes from ‘0’ to ‘1’ is counted as N_{0->1}^{step3} and is equal to the total number of memory cells 104 in regions R1′, R2′, and R3′. Subtracting the number of memory cells 104 in regions R1′ and R2′, the number of memory cells 104 with a threshold voltage in region R3′ is obtained (denoted N^{R3′}=N_{0->1}^{step3}−N^{R1′}−N^{R2′}).

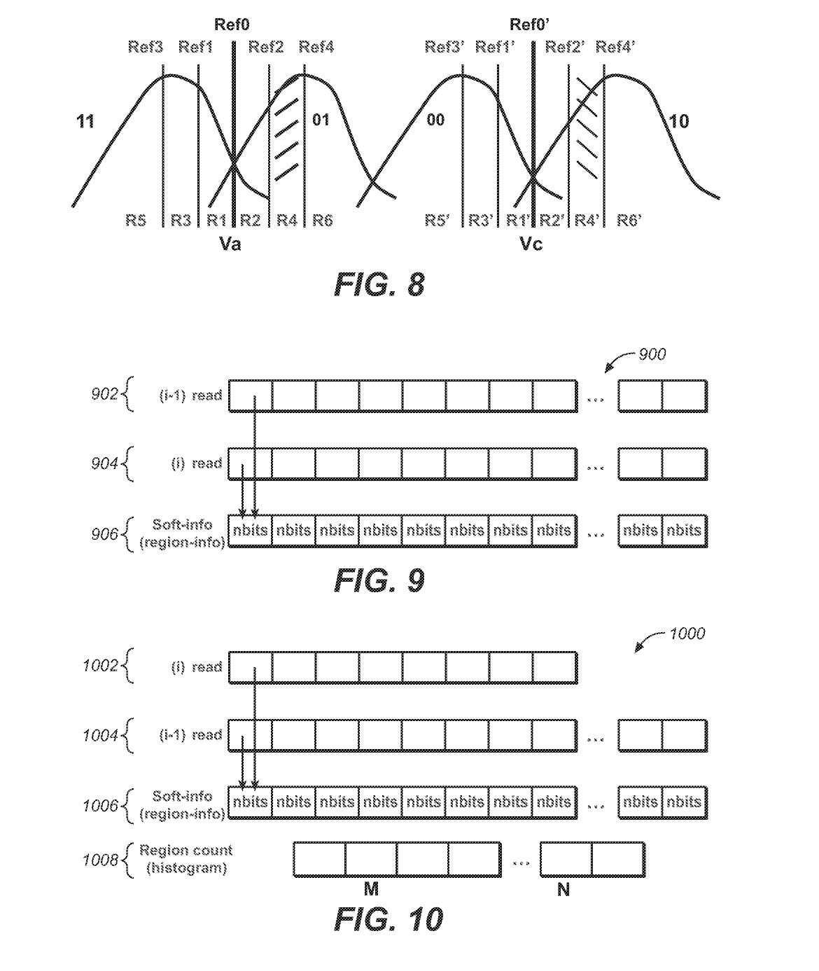

Then, with reference to FIG. 8, the upper page 106 of the memory 102 is read with reference voltages Ref4 and Ref4′, and memory cells 104 with a threshold voltage within region [Ref4, Ref4′] are read as ‘0’, while memory cells 104 with a threshold voltage beyond region [Ref4, Ref4′] are read as ‘1’. Compared to the raw page data read with Ref3 and Ref3′, the number of memory cells 104 read with a bit value that changes from ‘0’ to ‘1’ is counted as N_{0->1}^{step4} and is equal to the total number of memory cells 104 in regions R1, R2, R3, and R4. Subtracting the number of memory cells 104 in regions R1, R2, R3, and R4, the number of memory cells 104 with a threshold voltage in region R4 is obtained (denoted N^{R4}=N_{0->1}^{step4}−N^{R1}−N^{R2}−N^{R3}). Compared to the raw page data read with Ref3 and Ref3′, the number of memory cells 104 read with a bit value that changes from ‘1’ to ‘0’ is counted as N_{1->0}^{step4} and is equal to the total number of memory cells 104 in regions R1′, R2′, R3′, and R4′. Subtracting the number of memory cells 104 in regions R1′, R2′, R3′, and R4′, the number of memory cells 104 with a threshold voltage in region R4′ is obtained (denoted N^{R4′}=N_{1->0}^{step4}−N^{R1′}−N^{R2′}−N^{R3′}). Using this methodology, the numbers of memory cells 104 with threshold voltages programmed in regions R5, R6, R5′, R6′, and so on are obtained.

Referring now to FIG. 9, a buffer 900 (which implements, for example, the buffer 116 shown in FIG. 1) configured for logically sorting memory cells 104 into regions or bins associated with soft information obtained using multiple reads is described in accordance with example embodiments of the present disclosure. The buffer 900 is used to associate memory cells 104 with regions, such as the regions R1, R2, R3, R4, R5, R6, R7, and R8 described with reference to FIGS. 3 and 4, the regions R1, R2, R3, R4, R5, R6, R1′, R2′, R3′, R4′, R5′, and R6′ described with reference to FIGS. 5 through 8, and so forth. During a first read (e.g., an (i−1)th read), a group of memory cells 104 (e.g., a page such as the lower page 108 or the upper page 106, a codeword, and so on) of memory 102 is read with a first reference voltage or first reference voltages. Bit values from the raw data read are stored in a first area 902 of the buffer 900 (e.g., the (i−1) read area), which is sized based upon the number of memory cells 104 read (e.g., one page size, one codeword size, and so on).

Next, during a second read (e.g., an (i)th read), the same group of memory cells 104 is read with a second reference voltage or second reference voltages (e.g., as described with reference to FIGS. 3 and 4, or 5 through 8), and bit values from the raw data read are stored in a second area 904 of the buffer 900 (e.g., the (i) read area), which is also sized based upon the number of memory cells 104 read. In embodiments of the disclosure, memory cells 104 read with a bit value that changes are assigned a region value associated with soft information, such as a probability corresponding to a confidence in whether a bit value read from the memory 102 is correct, e.g., a log likelihood ratio (LLR) of the probability for the bit to be ‘1’ over the probability for the bit to be ‘0’. For example, with reference to FIGS. 3 and 4, memory cells 104 read with a bit value that changes (e.g., from ‘1’ to ‘0’ or ‘0’ to ‘1’) from the first read to the second read are assigned a region value in a third area 906 of the buffer 900 configured to store soft information (e.g., LLRs). In another example, with reference to FIGS. 5 through 8, memory cells 104 read with a bit value that changes from ‘1’ to ‘0’ from the first read to the second read are assigned a region value in the third area 906 of the buffer 900, while memory cells 104 read with a bit value that changes from ‘0’ to ‘1’ from the first read to the second read are assigned a different region value in the third area 906 of the buffer 900. In example embodiments, the region values assigned to the memory cells 104 are determined using a methodology such as that described with reference to FIGS. 3 and 4, FIGS. 5 through 8, and so forth. Bit values that remain unchanged from the first read to the second read are not necessarily assigned a region value.

In embodiments of the disclosure, an initial value is assigned to the memory cells 104 in the third area 906 of the buffer 900. For example, before the first read (e.g., the (i−1)th read), all region values of the n-bits are assigned a value that denotes invalidity (e.g., a value of ‘−1’). This initial value does not correspond to any valid region (e.g., not corresponding to any of the regions R1, R2, R3, R4, R5, R6, R7, and R8 described with reference to FIGS. 3 and 4, the regions R1, R2, R3, R4, R5, R6, R1′, R2′, R3′, R4′, R5′, and R6′ described with reference to FIGS. 5 through 8, and so forth).

Then, all previous read-retry bit values except the most recent bit values (e.g., from the (i)th read) are discarded, and the same group of memory cells 104 is read with a third reference voltage or third reference voltages (e.g., as described with reference to FIGS. 3 and 4, or 5 through 8) during a third read (e.g., an (i+1)th read). During the third read, bit values from the raw data read are stored in the first area 902 of the buffer 900 (e.g., the (i−1) read area shown in FIG. 9). In embodiments of the disclosure, memory cells 104 read with a bit value that changes from the second read to the third read are assigned a new region value or new region values in the third area 906 of the buffer 900 (e.g., as previously described with reference to FIGS. 3 and 4, or FIGS. 5 through 8). Bit values that remain unchanged from the second read to the third read are not necessarily assigned a region value. Using this methodology, the procedures described for alternately storing bit values from one raw data read and then another raw data read in two different areas of the buffer 900 are iteratively executed (e.g., until all read reference voltages have been tried and/or all memory cells 104 of the group have been assigned a region value).

For example, after the last read retry, each bit has been assigned a value in the third area 906 of the buffer 900 (e.g., either an initial value or a region value). In embodiments of the disclosure, the controller 110 maintains an LLR table for mapping the LLR (n-bits) to the bits assigned to each region (e.g. the regions R3, R4, R3′, R4′, etc.). For the bits that are not assigned a valid region, the memory cells 104 are associated with either a region of highly confident ‘0’ (e.g., the regions R6 and/or R5′ with reference to FIG. 8) or highly confident ‘1’ (e.g., the regions R5 and/or R6′ with reference to FIG. 8). In order to assign a memory cell 104 to a region, the bit value in the second area 904 of the buffer 900 is examined. If the value is ‘0’, the memory cell 104 is assigned a value denoted −MAX. If the value is ‘1’, the memory cell 104 is assigned a value denoted +MAX. It should be noted that the ‘+’ or ‘−’ signs for ‘0’ or ‘1’ values can be determined based upon a particular implementation. For instance, where the LLR is defined as the log of the probability of a bit to be ‘1’ over the bit to be ‘0’, the values given in the present example are used. In some embodiments, where the soft information is four (4) bits, −MAX is defined with a value of minus eight (−8) and +MAX is defined with a value of plus seven (+7). However, these values are provided by way of example only and are not meant to limit the present disclosure. In other embodiments, different values are used (e.g., depending upon a particular implementation).

Referring now to FIG. 10, another buffer 1000 (which implements, for example, the buffer 116 shown in FIG. 1) configured for logically sorting memory cells 104 into regions or bins associated with soft information obtained using multiple reads is described in accordance with example embodiments of the present disclosure. In this example, the buffer 1000 includes a first area 1002 sized based upon the number of bit values passed between a controller and the memory 102 at one time. For example, the first area 1002 comprises an eight-bit (8-bit) buffer sized for serial reads from flash memory to a flash controller via an eight-bit (8-bit) wide flash pin interface. However, eight (8) bits are provided by way of example only and are not meant to limit the present disclosure. In other embodiments, the first area 1002 stores fewer than eight (8) bits or more than eight (8) bits (e.g., sixteen (16) bits). During a first read (e.g., an (i−1)th read), a group of memory cells 104 (e.g., a page such as the lower page 108 or the upper page 106, a codeword, and so on) of memory 102 is read with a first reference voltage or first reference voltages. Bit values from the raw data read are stored in a second area 1004 of the buffer 1000 (e.g., the (i−1) read area), which is sized based upon the number of memory cells 104 read (e.g., one page size, one codeword size, and so on).

Next, during a second read (e.g., an (i)th read), the same group of memory cells 104 is read with a second reference voltage or second reference voltages (e.g., as described with reference to FIGS. 3 and 4, or 5 through 8), and the first eight (8) bit values from the raw data read are stored in the first area 1002 of the buffer 1000 (e.g., the (i) read area). In embodiments of the disclosure, memory cells 104 read with a bit value that changes are assigned a region value associated with soft information, such as a probability corresponding to a confidence in whether a bit value read from the memory 102 is correct, e.g., an LLR of the probability for the bit to be ‘1’ over the probability for the bit to be ‘0’. For example, with reference to FIGS. 3 and 4, memory cells 104 read with a bit value that changes (e.g., from ‘1’ to ‘0’ or ‘0’ to ‘1’) from the first read to the second read are assigned a region value in a third area 1006 of the buffer 1000 configured to store soft information (e.g., LLRs). In another example, with reference to FIGS. 5 through 8, memory cells 104 read with a bit value that changes from ‘0’ to ‘1’ from the first read to the second read are assigned a region value (e.g., region value M) in the third area 1006 of the buffer 1000, while memory cells 104 read with a bit value that changes from ‘1’ to ‘0’ from the first read to the second read are assigned a different region value (e.g., region value N) in the third area 1006 of the buffer 1000. In example embodiments, the region values assigned to the memory cells 104 are determined using a methodology such as that described with reference to FIGS. 3 and 4, FIGS. 5 through 8, and so forth. Bit values that remain unchanged from the first read to the second read are not necessarily assigned a region value.

In embodiments of the disclosure, an initial value is assigned to the memory cells 104 in the third area 1006 of the buffer 1000. For example, before the first read (e.g., the (i−1)th read), all region values of the n-bits are assigned a value that denotes invalidity (e.g. a value of ‘−1’). This initial value does not correspond to any valid region (e.g., not corresponding to any of the regions R1, R2, R3, R4, R5, R6, R7, and R8 described with reference to FIGS. 3 and 4, the regions R1, R2, R3, R4, R5, R6, R1′, R2′, R3′, R4′, R5′, and R6′ described with reference to FIGS. 5 through 8, and so forth).

Then, the number of memory cells 104 assigned a region value or region values are counted. For example, the numbers of memory cells 104 assigned region values M and N are counted and denoted as m and n, respectively. Next, the number m is added to the value stored in the M-th entry in a histogram area 1008 of the buffer 1000, and the number n is added to the value stored in the N-th entry in the histogram area 1008 of the buffer 1000. In this example, the other histogram entries in the buffer 1000 are unchanged. In some embodiments, the histogram area 1008 of the buffer 1000 stores sixteen (16) values, and in other embodiments, the histogram area 1008 of the buffer 1000 stores thirty-two (32) values. However, these histogram sizes are provided by way of example only and are not meant to limit the present disclosure. In other embodiments, the histogram area 1008 of the buffer 1000 store fewer than sixteen (16) values, between sixteen (16) and thirty-two (32) values, more than thirty-two (32) values, and so forth. Then, a write back operation is performed to update the data in the second area 1004 of the buffer 1000. For example, the first eight (8) bit values from the second read are copied to overwrite the first eight (8) bits (e.g., bits one (1) through eight (8)) of the second area 1004 of the buffer 1000 (e.g., the (i−1) read area). In this way, the first eight (8) bits of the (i−1)th read are overwritten by the first eight (8) bit values of the (i)th read. Next, the second eight (8) bit values from the raw data read are stored in the first area 1002 of the buffer 1000 (e.g., the (i) read area). Memory cells 104 read with a bit value that changes are assigned a region value associated with soft information (e.g., as previously described). Bit values that remain unchanged from the first read to the second read are not necessarily assigned a region value.

Then, the count or counts of memory cells 104 assigned a region value or region values are updated. For example, the numbers of memory cells 104 assigned region values M and N are counted and denoted as m and n, respectively. Next, the number m is added to the value stored in the M-th entry in the histogram area 1008 of the buffer 1000, and the number n is added to the value stored in the N-th entry in the histogram area 1008 of the buffer 1000. In this example, the other histogram entries are unchanged. Then, a write back operation is performed to update the data in the second area 1004 of the buffer 1000. For example, the second eight (8) bit values from the second read are copied to overwrite the second eight (8) bits (e.g., bits nine (9) through sixteen (16)) of the second area 1004 of the buffer 1000 (e.g., the (i−1) read area). In this way, the second eight (8) bits of the (i−1)th read are overwritten by the second eight (8) bit values of the (i)th read. Next, the third eight (8) bit values from the raw data read are stored in the first area 1002 of the buffer 1000 (e.g., the (i) read area). Memory cells 104 read with a bit value that changes are assigned a region value associated with soft information (e.g., as previously described). Bit values that remain unchanged from the first read to the second read are not necessarily assigned a region value.

Then, the count or counts of memory cells 104 assigned a region value or region values are updated. For example, the numbers of memory cells 104 assigned region values M and N are counted and denoted as m and n, respectively. Next, the number m is added to the value stored in the M-th entry in the histogram area 1008 of the buffer 1000, and the number n is added to the value stored in the N-th entry in the histogram area 1008 of the buffer 1000. In this example, the other histogram entries are unchanged. Then, a write back operation is performed to update the data in the second area 1004 of the buffer 1000. For example, the third eight (8) bit values from the second read are copied to overwrite the third eight (8) bits (e.g., bits seventeen (17) through twenty-four (24)) of the second area 1004 of the buffer 1000 (e.g., the (i−1) read area). In this way, the third eight (8) bits of the (i−1)th read are overwritten by the third eight (8) bit values of the (i)th read. Using this methodology, successive groups of bit values from the second read are stored in the first area 1002 of the buffer 1000, compared to bit values from the first read to assign region values to memory cells 104 read with a bit value that changes, and then written back to the second area 1004 of the buffer 1000 (e.g., until all bit values from the second read have been compared to the bit values from the first read).

Then, all previous read-retry bit values except the most recent bit values (e.g., bit values from the (i)th read stored in the second area 1004 of the buffer 1000) are discarded, and the same group of memory cells 104 is read with a third reference voltage or third reference voltages (e.g., as described with reference to FIGS. 3 and 4, or 5 through 8) during a third read (e.g., an (i+1)th read). During the third read, successive groups of bit values from the raw data read are stored in the first area 1002 of the buffer 1000 (e.g., the (i) read area shown in FIG. 10). In embodiments of the disclosure, memory cells 104 read with a bit value that changes from the second read to the third read are assigned a new region value or new region values in the third area 1006 of the buffer 1000 (e.g., as previously described with reference to FIGS. 3 and 4, or FIGS. 5 through 8). Bit values that remain unchanged from the second read to the third read are not necessarily assigned a region value. Additionally, the count or counts of memory cells 104 assigned a region value or region values are updated. In this manner, successive groups of bit values from the third read are stored in the first area 1002 of the buffer 1000, compared to bit values from the second read to assign region values to memory cells 104 read with a bit value that changes, and then written back to the second area 1004 of the buffer 1000 (e.g., until all bit values from the third read have been compared to the bit values from the second read) Using this methodology, the procedures described for storing groups of bit values from one raw data read in one area of the buffer 1000 and then writing the groups of bit values back to another area of the buffer 1000 are iteratively executed (e.g., until all read reference voltages have been tried and/or all memory cells 104 of the group have been assigned a region value).

For example, after the last read retry, each bit has been assigned a value in the third area 1006 of the buffer 1000 (e.g., either an initial value or a region value). In embodiments of the disclosure, the controller 110 maintains an LLR table for mapping the LLR (n-bits) to the bits assigned to each region (e.g. the regions R3, R4, R3′, R4′, etc.). For the bits that are not assigned a valid region, the memory cells 104 are associated with either a region of highly confident ‘0’ (e.g., the regions R6 and/or R5′ with reference to FIG. 8) or highly confident ‘1’ (e.g., the regions R5 and/or R6′ with reference to FIG. 8). In order to assign a memory cell 104 to a region, the bit value in the second area 1004 of the buffer 1000 is examined. If the value is ‘0’, the memory cell 104 is assigned a value denoted −MAX. If the value is ‘1’, the memory cell 104 is assigned a value denoted +MAX. It should be noted that the ‘+’ or ‘−’ signs for ‘0’ or ‘1’ values can be determined based upon a particular implementation. For instance, where the LLR is defined as the log of the probability of a bit to be ‘1’ over the bit to be ‘0’, the values given in the present example are used. In some embodiments, where the soft information is four (4) bits, −MAX is defined with a value of minus eight (−8) and +MAX is defined with a value of plus seven (+7). However, these values are provided by way of example only and are not meant to limit the present disclosure. In other embodiments, different values are used (e.g., depending upon a particular implementation).

In this manner, techniques in accordance with the present disclosure are used to determine histograms for both upper pages 106 of memory 102 and lower pages 108 of memory 102. Further, for the upper pages 106 of the memory 102, Va and Vc are changed simultaneously, while the information collected is leveraged to learn both the histogram and soft information. This technique can identify the threshold voltages of memory cells near the Va region or Vc region by reading most significant bit (MSB) pages (e.g., without additional least significant bit (LSB) page reading). Additionally, rather than discard other useful information, such as ‘1’ to ‘0’ and ‘0’ to ‘1’ bit value changes for memory cells (e.g., during upper page reading), techniques of the present disclosure use bit value changes to assign a fine grained threshold voltage region to each memory cell 104. Further, these techniques can be performed online (e.g., in real time, on the fly, and so on). For example, soft information (e.g., LLR) is calculated for LDPC in real time, immediately after read retry completion. Further, the amount of hardware silicon area (e.g., controller chip space) required for LLR calculation can be significantly reduced (e.g., with respect to controller chips that do not use the techniques described herein). For example, the area of a controller chip is reduced by a factor of ½ⁿ, where n denotes the bit-width for LLR. In embodiments of the disclosure, buffer overhead is also reduced. For example, buffer cost does not increase with soft information bit width.

Referring again to FIG. 1, the system 100, including some or all of its components, can operate under computer control. For example, the processor 112 can be included with or in a system 100 to control the components and functions of systems 100 described herein using software, firmware, hardware (e.g., fixed logic circuitry), manual processing, or a combination thereof. The terms “controller,” “functionality,” “service,” and “logic” as used herein generally represent software, firmware, hardware, or a combination of software, firmware, or hardware in conjunction with controlling the systems 100. In the case of a software implementation, the module, functionality, or logic represents program code that performs specified tasks when executed on a processor (e.g., central processing unit (CPU) or CPUs). The program code can be stored in one or more computer-readable memory devices (e.g., internal memory and/or one or more tangible media), and so on. The structures, functions, approaches, and techniques described herein can be implemented on a variety of commercial computing platforms having a variety of processors.

The processor 112 provides processing functionality for the system 100 and can include any number of processors, micro-controllers, or other processing systems, and resident or external memory for storing data and other information accessed or generated by the system 100. The processor 112 can execute one or more software programs that implement techniques described herein. The processor 112 is not limited by the materials from which it is formed or the processing mechanisms employed therein and, as such, can be implemented via semiconductor(s) and/or transistors (e.g., using electronic integrated circuit (IC) components), and so forth.

The memory 114 is an example of tangible, computer-readable storage medium that provides storage functionality to store various data associated with operation of the system 100, such as software programs and/or code segments, or other data to instruct the processor 112, and possibly other components of the system 100, to perform the functionality described herein. Thus, the memory 114 can store data, such as a program of instructions for operating the system 100 (including its components), and so forth. It should be noted that while a single memory 114 is described, a wide variety of types and combinations of memory (e.g., tangible, non-transitory memory) can be employed. The memory 114 can be integral with the processor 112, can comprise stand-alone memory, or can be a combination of both.

The memory 114 can include, but is not necessarily limited to: removable and non-removable memory components, such as random-access memory (RAM), read-only memory (ROM), flash memory (e.g., a secure digital (SD) memory card, a mini-SD memory card, and/or a micro-SD memory card), magnetic memory, optical memory, universal serial bus (USB) memory devices, hard disk memory, external memory, and so forth. In implementations, the system 100 and/or the memory 114 can include removable integrated circuit card (ICC) memory, such as memory provided by a subscriber identity module (SIM) card, a universal subscriber identity module (USIM) card, a universal integrated circuit card (UICC), and so on.

The communications interface 118 is operatively configured to communicate with components of the system 100. For example, the communications interface 118 can be configured to transmit data for storage in the memory 102, retrieve data from storage in the memory 102, and so forth. The communications interface 118 is also communicatively coupled with the processor 112 to facilitate data transfer between components of the system 100 and the processor 112 (e.g., for communicating inputs to the processor 112 received from a device communicatively coupled with the system 100). It should be noted that while the communications interface 118 is described as a component of a system 100, one or more components of the communications interface 118 can be implemented as external components communicatively coupled to the system 100 via a wired and/or wireless connection. The system 100 can also comprise and/or connect to one or more input/output (I/O) devices (e.g., via the communications interface 118), including, but not necessarily limited to: a display, a mouse, a touchpad, a keyboard, and so on.

The communications interface 118 and/or the processor 112 can be configured to communicate with a variety of different networks, including, but not necessarily limited to: a wide-area cellular telephone network, such as a 3G cellular network, a 4G cellular network, or a global system for mobile communications (GSM) network; a wireless computer communications network, such as a WiFi network (e.g., a wireless local area network (WLAN) operated using IEEE 802.11 network standards); an internet; the Internet; a wide area network (WAN); a local area network (LAN); a personal area network (PAN) (e.g., a wireless personal area network (WPAN) operated using IEEE 802.15 network standards); a public telephone network; an extranet; an intranet; and so on. However, this list is provided by way of example only and is not meant to limit the present disclosure. Further, the communications interface 118 can be configured to communicate with a single network or multiple networks across different access points.

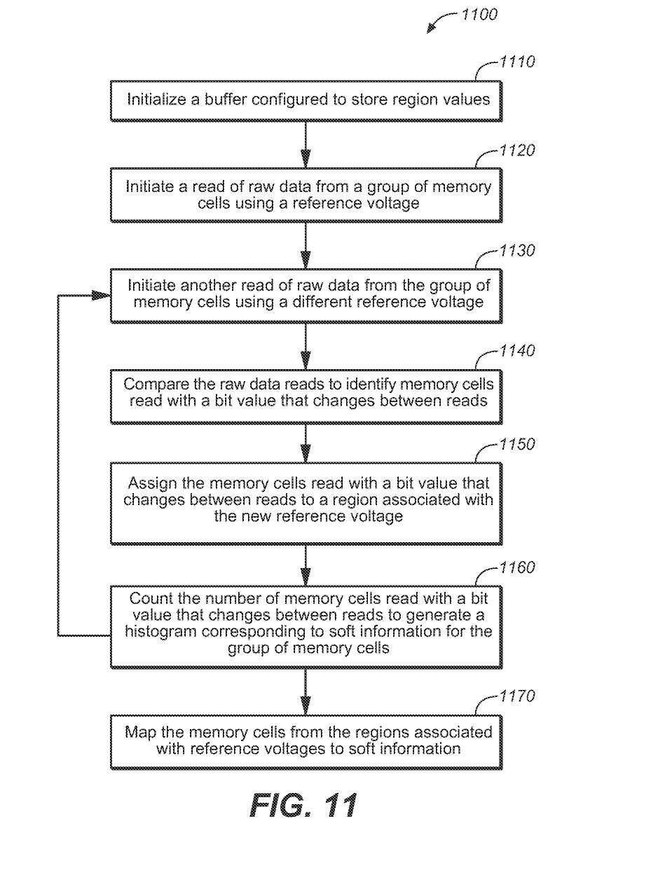

Referring now to FIG. 11, example techniques for assigning memory cells to regions associated with soft information obtained using multiple reads and generating a histogram corresponding to soft information for the memory cells are described. FIG. 11 depicts a process 1100, in an example embodiment, where successive raw data reads with different reference voltages from a group of memory cells are compared to identify memory cells read with a bit value that changes between reads. The memory cells read with a bit value that changes are assigned to regions associated with a reference voltage. The number of memory cells read with a bit value that changes are also counted to generate a histogram corresponding to soft information for the memory cells.

In the process illustrated, an area of a buffer configured to store region values is initialized (Bock 1110). For example, with reference to FIGS. 1, 9, and 10, initial values are assigned to the memory cells 104 (e.g., in the third area 906 of the buffer 900 or the third area 1006 of the buffer 1000). Next, a read of raw data from a group of memory cells is initiated using a reference voltage (Block 1120). For example, with reference to FIGS. 1, 3, and 4, a first raw data read of a lower page 108 of memory 102 is initiated by the processor 112 with a first reference voltage. With reference to FIGS. 1 and 5 through 8, a first raw data read of an upper page 106 of memory 102 is initiated by the processor 112 with a first two reference voltages. Then, another read of raw data from the group of memory cells is initiated using a different reference voltage (Block 1130). For example, with reference to FIGS. 1, 3, and 4, a second raw data read of a lower page 108 of memory 102 is initiated by the processor 112 with a second reference voltage. With reference to FIGS. 1 and 5 through 8, a second raw data read of an upper page 106 of memory 102 is initiated by the processor 112 with a second two reference voltages.

Next, the raw data reads are compared to identify memory cells read with a bit value that changes between reads (Block 1140). Then, the memory cells read with a bit value that changes between reads are assigned to a region associated with the new reference voltage (Block 1150). For example, with reference to FIGS. 1, 3, 4, and 9, memory cells 104 read with a bit value that changes (e.g., from ‘1’ to ‘0’ or ‘0’ to ‘1’) from the first read to the second read are assigned a region value in a third area 906 of the buffer 900. With reference to FIGS. 1 and 5 through 9, memory cells 104 read with a bit value that changes from ‘1’ to ‘0’ from the first read to the second read are assigned a region value in the third area 906 of the buffer 900, while memory cells 104 read with a bit value that changes from ‘0’ to ‘1’ from the first read to the second read are assigned a different region value in the third area 906 of the buffer 900.

Next, the number of memory cells read with a bit value that changes between reads is counted to generate a histogram corresponding to soft information for the group of memory cells (Block 1160). For example, with reference to FIG. 10, the number of memory cells 104 assigned a region value or region values are counted. For example, the numbers of memory cells 104 assigned region values M and N are counted and denoted as m and n, respectively. Next, the number m is added to the value stored in the M-th entry in the histogram area 1008 of the buffer 1000, and the number n is added to the value stored in the N-th entry in the histogram area 1008 of the buffer 1000. Then, the process 1100 loops back to Block 1130, where a third read of raw data from a group of memory cells is initiated using a third reference voltage, the second read of raw data is compared to the third read of raw data to identify memory cells read with a bit value that changes between the second read of raw data and the third read of raw data (Block 1140), and so forth. In embodiments of the disclosure, this process is repeated until all read reference voltages have been tried and/or all memory cells of the group have been assigned a region value. Next, the memory cells 104 are mapped from the region values determined based upon the reference voltages to soft information (Block 1170), such as LLR (n-bits). For instance, with reference to FIG. 1, the controller 110 maintains an LLR table for mapping the LLR (n-bits) to the bits assigned to each region. It should be noted that mapping from the region information to LLR does not necessarily use an additional buffer. For example, final LLR values are buffered in the third area 906 of the buffer 900 or the third area 1006 of the buffer 1000 and used to overwrite the region information.

Generally, any of the functions described herein can be implemented using hardware (e.g., fixed logic circuitry such as integrated circuits), software, firmware, manual processing, or a combination thereof. Thus, the blocks discussed in the above disclosure generally represent hardware (e.g., fixed logic circuitry such as integrated circuits), software, firmware, or a combination thereof. In the instance of a hardware configuration, the various blocks discussed in the above disclosure may be implemented as integrated circuits along with other functionality. Such integrated circuits may include all of the functions of a given block, system, or circuit, or a portion of the functions of the block, system, or circuit. Further, elements of the blocks, systems, or circuits may be implemented across multiple integrated circuits. Such integrated circuits may comprise various integrated circuits, including, but not necessarily limited to: a monolithic integrated circuit, a flip chip integrated circuit, a multichip module integrated circuit, and/or a mixed signal integrated circuit. In the instance of a software implementation, the various blocks discussed in the above disclosure represent executable instructions (e.g., program code) that perform specified tasks when executed on a processor. These executable instructions can be stored in one or more tangible computer readable media. In some such instances, the entire system, block, or circuit may be implemented using its software or firmware equivalent. In other instances, one part of a given system, block, or circuit may be implemented in software or firmware, while other parts are implemented in hardware.

Although embodiments of the disclosure have been described in language specific to structural features and/or methodological acts, it is to be understood that the subject matter defined in the appended claims is not necessarily limited to the specific embodiments described. Although various configurations are discussed, the apparatus, systems, subsystems, components and so forth can be constructed in a variety of ways without departing from teachings of this disclosure. Rather, the specific features and acts are disclosed as embodiments of implementing the claims.

What is claimed is:

1. A system comprising:
a processor configured to read information from a plurality of memory cells; and
a memory having computer executable instructions stored thereon, the computer executable instructions configured for execution by the processor to:
initiate a first read of raw data from a group of memory cells using at least a first reference voltage;
initiate a second read of raw data from the group of memory cells using at least a second reference voltage different from the at least the first reference voltage;
compare the first read of raw data to the second read of raw data to identify memory cells of the group of memory cells read with a bit value that changes between the first read of raw data and the second read of raw data; and
assign the memory cells read with a bit value that changes between the first read of raw data and the second read of raw data to at least one region associated with the at least the second reference voltage.

2. The system as recited in claim 1, wherein the computer executable instructions are configured for execution by the processor to count the number of memory cells read with a bit value that changes between the first read of raw data and the second read of raw data to generate a histogram corresponding to soft information for the group of memory cells.

3. The system as recited in claim 1, wherein the group of memory cells comprises a group of flash memory cells.

4. The system as recited in claim 3, wherein the group of flash memory cells comprises a group of multiple level cell flash memory cells.

5. The system as recited in claim 1, wherein the at least the first reference voltage comprises at least a first two reference voltages, the at least the second reference voltage comprises at least a second two reference voltages, and assigning the memory cells read with a bit value that changes between the first read of raw data and the second read of raw data to at least one region associated with the at least the second reference voltage comprises assigning the memory cells read with a bit value that changes between the first read of raw data and the second read of raw data to one of two regions associated with one of the at least the second two reference voltages.

6. The system as recited in claim 1, wherein the first raw data read is stored in a first area of a buffer, the second raw data read is stored in a second area of the buffer, and the first raw data read is discarded subsequent to assigning the memory cells read with a bit value that changes between the first read of raw data and the second read of raw data to the at least one region associated with the at least the second reference voltage.

7. The system as recited in claim 6, wherein the first area of the buffer comprises a size based upon a number of bit values passed between the processor and the memory cells at one time, and the second area of the buffer is sized based upon a number of the group of memory cells.

8. The system as recited in claim 6, wherein the first area of the buffer and the second area of the buffer are each sized based upon a number of the group of memory cells.

9. A non-transitory computer-readable storage medium having computer executable instructions configured to implement histogram and soft information learning for electronic computer storage, the computer executable instructions comprising:
initiating, by a processor, a first read of raw data from a group of flash memory cells using at least a first reference voltage;
initiating, by the processor, a second read of raw data from the group of flash memory cells using at least a second reference voltage different from the at least the first reference voltage;
comparing, by the processor, the first read of raw data to the second read of raw data to identify memory cells of the group of flash memory cells read with a bit value that changes between the first read of raw data and the second read of raw data;
assigning, by the processor, the memory cells read with a bit value that changes between the first read of raw data and the second read of raw data to at least one region associated with the at least the second reference voltage; and
counting, by the processor, the number of memory cells read with a bit value that changes between the first read of raw data and the second read of raw data to generate a histogram corresponding to soft information for the group of memory cells.

10. The non-transitory computer-readable storage medium as recited in claim 9, wherein the group of flash memory cells comprises a group of multiple level cell flash memory cells.

11. The non-transitory computer-readable storage medium as recited in claim 9, wherein the at least the first reference voltage comprises at least a first two reference voltages, the at least the second reference voltage comprises at least a second two reference voltages, and assigning the memory cells read with a bit value that changes between the first read of raw data and the second read of raw data to at least one region associated with the at least the second reference voltage comprises assigning the memory cells read with a bit value that changes between the first read of raw data and the second read of raw data to one of two regions associated with one of the at least the second two reference voltages.

12. The non-transitory computer-readable storage medium as recited in claim 9, wherein the first raw data read is stored in a first area of a buffer, the second raw data read is stored in a second area of the buffer, and the first raw data read is discarded subsequent to assigning the memory cells read with a bit value that changes between the first read of raw data and the second read of raw data to the at least one region associated with the at least the second reference voltage.

13. The non-transitory computer-readable storage medium as recited in claim 12, wherein the first area of the buffer comprises a size based upon a number of bit values passed between the processor and the memory cells at one time, and the second area of the buffer is sized based upon a number of the group of memory cells.

14. The non-transitory computer-readable storage medium as recited in claim 12, wherein the first area of the buffer and the second area of the buffer are each sized based upon a number of the group of memory cells.

15. A computer-implemented method for implementing histogram and soft information learning for electronic computer storage, the computer-implemented method comprising:
initiating, by a processor, a first read of raw data from a group of flash memory cells using a first two reference voltages;
initiating, by the processor, a second read of raw data from the group of flash memory cells using a second two reference voltages different from the first two reference voltages;
comparing, by the processor, the first read of raw data to the second read of raw data to identify memory cells of the group of flash memory cells read with a bit value that changes between the first read of raw data and the second read of raw data; and
causing the processor to assign the memory cells read with a bit value that changes between the first read of raw data and the second read of raw data to one of two regions associated with the second two reference voltages.

16. The computer-implemented method as recited in claim 15, further comprising counting, by the processor, the number of memory cells read with a bit value that changes between the first read of raw data and the second read of raw data to generate a histogram corresponding to soft information for the group of flash memory cells.

17. The computer-implemented method as recited in claim 15, wherein the group of flash memory cells comprises a group of multiple level cell flash memory cells.

18. The computer-implemented method as recited in claim 15, wherein the first raw data read is stored in a first area of a buffer, the second raw data read is stored in a second area of the buffer, and the first raw data read is discarded immediately subsequent to assigning the memory cells read with a bit value that changes between the first read of raw data and the second read of raw data to the one of two regions associated with the second two reference voltages.

19. The computer-implemented method as recited in claim 18, wherein the first area of the buffer comprises a size based upon a number of bit values passed between the processor and the memory cells at one time, and the second area of the buffer is sized based upon a number of the group of flash memory cells.

20. The computer-implemented method as recited in claim 18, wherein the first area of the buffer and the second area of the buffer are each sized based upon a number of the group of flash memory cells.
